(19) United States
(12) Patent Application Publication
(10) Pub. No.: US 2021/0335930 A1
(43) Pub. Date: Oct. 28, 2021

(54) DISPLAY PANEL AND DISPLAY DEVICE

(71) Applicant: WUHAN CHINA STAR OPTOELECTRONICS SEMICONDUCTOR DISPLAY TECHNOLOGY CO., LTD., Wuhan, Hubei (CN)

(72) Inventors: Min ZHENG, Wuhan, Hubei (CN); Yangqi OU, Wuhan, Hubei (CN); Yang ZHOU, Wuhan, Hubei (CN)

(21) Appl. No.: 16/471,254

(22) PCT Filed: Apr. 24, 2019
(86) PCT No.: PCT/CN2019/083994

§ 371 Date: Jun. 19, 2019

(30) Foreign Application Priority Data
Mar. 12, 2019 (CN) 201910184906.6

(51) Int. Cl. H01L 27/32; H01L 51/52

(52) U.S. Cl. CPC H01L 27/3246; H01L 51/5253

(57) ABSTRACT

The present invention provides a display panel and a display device. The display panel includes a substrate layer, a thin film transistor layer, a flat layer, a pixel definition layer and a thin film packaging layer arranged in turn. The pixel definition layer forms a first pixel and a second pixel, which are adjacent but spaced. The pixel definition layer and the flat layer are provided with a through hole between the first pixel and the second pixel. The through hole is filled with a filling layer. The advantages of the invention are that the transmittance of a camera module under the substrate layer is increased, the diameter of the through hole is reduced, and the full screen is achieved.

### BACKGROUND OF THE INVENTION

### 1. Field of the Invention

The present invention relates to a technical field of a display panel, and more particularly to a display panel and a display device.

### 2. Description of the Prior Art

A full screen design has developed rapidly in the past two years. A full screen, represented by a notch screen and a water drop screen, gradually occupies the mainstream of the market. The main feature of the full screen is to pursue a greater proportion of screens. At present, there is no real full screen in the market, but manufacturers are developing. The design idea is to dig a hole in the screen, place a front camera, and hide a camera module in the panel. In order to ensure that the camera module can receive more light, it is necessary to have a high requirement for the transmittance of the laminated panels.

The camera module is located under a PI (Polyimide) film, and the PI material is a transparent organic material. Usually a double PI structure is used as a substrate. In order to ensure that the camera module can receive more light, the diameter of the hole dug in the panel is greater, which leads to the failure of a great screen proportion.

Hence, it is necessary to develop a new display panel to overcome the defect in the prior art.

### 3. Technical Problem

One object of the present invention is to provide a display panel to solve the technical problems of small transmittance and large hole diameter in the prior art.

### BRIEF SUMMARY OF THE INVENTION

### Technical Solutions

To realize the above object, the present invention provides a display panel, including a substrate layer, a thin film transistor layer, a flat layer, a pixel definition layer and a thin film packaging layer arranged in turn. The pixel definition layer forms a first pixel and a second pixel, which are adjacent but spaced. Wherein the pixel definition layer and the flat layer are provided with a through hole between the first pixel and the second pixel. The through hole is filled with a filling layer.

Further, in other embodiments, the filling layer adopts a transparent organic material, a transmittance of which is greater than that of the pixel definition layer and the flat layer.

Further, in other embodiments, the thin film packaging layer includes a first inorganic layer, an organic layer arranged on the first inorganic layer, and a second inorganic layer arranged on the organic layer.

Further, in other embodiments, the filling layer includes a first filling layer on an inner wall of the through hole and a second filling layer on the first filling layer; the first filling layer and the first inorganic layer are in the same layer, and the second filling layer and the organic layer are in the same layer.

Further, in other embodiments, the substrate layer is provided with a groove corresponding to the through hole on one side of the substrate layer away from the thin film transistor layer for accommodating an electronic component.

Further, in other embodiments, a depth of the groove is 20%-80% of a thickness of the substrate layer.

Further, in other embodiments, a cross-section shape of the through hole is rectangular.

Further, in other embodiments, a cross-section shape of the through hole is inverted trapezoid.

Further, in other embodiments, the through hole forms an angle between a sidewall and a bottom thereof, and the angle is between 90 degrees and 120 degrees. The sidewall of the through hole can act as a reflector for reflecting lights entering the display panel from outside.

The other object of the present invention is to provide a display device, including a body, wherein the body is provided with a display panel and an electronic component located under a through hole of the display panel.

Beneficial Effect

Compared with the prior art, the beneficial effects of the present invention lie in: the present invention provides the display panel and the display device. There forms the through hole between the two pixels, and removes the flat layer and the pixel definition layer in the through hole. The removed part can be replaced by a material with greater transmittance, and the thickness of the substrate layer corresponding to the through hole is reduced appropriately to improve the transmittance of the electronic components under the substrate layer. The diameter of the through hole is reduced for obtaining the full screen or the greater screen proportion. Moreover, an original line layer and the thin film packaging layer are retained to provide a maximum barrier function for the water and oxygen in the through hole area.

### BRIEF DESCRIPTION OF THE DRAWINGS

For more clearly illustrating the technical scheme in the embodiment of the present invention, the following text will briefly introduce the accompanying drawings used in the embodiment. It is obvious that the accompanying drawings in the following description are only some embodiments of the present invention. For the technical personnel of the field, other drawings can also be obtained from these drawings without paying creative work.

FIG. 1 is a sectional schematic view of a display panel provided by a first embodiment of the present invention;

FIG. 2 is a top view of the display panel provided by the first embodiment of the present invention;

FIG. 3 is a sectional schematic view of the display panel provided by a second embodiment of the present invention; and

FIG. 4 is a sectional schematic view of the display panel provided by a third embodiment of the present invention.

### DETAILED DESCRIPTION OF THE PREFERRED EMBODIMENTS

The following text will clearly and completely describe embodiments of the present invention with reference to the accompanying drawings. Obviously, the described embodiments are only part of the embodiments of the invention, not all of the embodiments. Based on the embodiments of the present invention, all of the other embodiments acquired by those skilled in the art without creative labor will fall within the scope of the present invention.

The specific structural and functional details disclosed herein are only representative and are intended for the purpose of describing exemplary embodiments of the present invention. However, the present invention can be implemented in many alternative forms and should not be construed as being limited only to the embodiments described herein.

In the following description of the present invention, it should be noted that terminology, such as “upper”, “lower”, “inside”, “outside”, “surface” etc., are used with reference to the orientation or position of the accompanying drawings. They are intended to better and more clearly describe and understand the present invention, but not intended to instruct or imply that the referred device or element has to be of a certain direction, or operated or constructed along a certain direction. Therefore, these terms cannot be interpreted as limitations to the present invention. Moreover, the terms, such as “first” and “second”, and the like, are only used to distinguish one entity or operation from another entity or operation, but not understood to instruct or imply the relative importance or implicitly indicate the number of technical characteristics indicated. Further, the features defined by “first” and “second” may explicitly or implicitly include one or more the sorts of features. In the description of the present invention, “multiple” means two or more unless otherwise specified. In addition, the term “including” and any variation thereof are intended to cover exclusive inclusions.

### Embodiment 1

Please referring to FIG. 1, FIG. 1 is a sectional schematic view of a display panel provided by the embodiment. In order to achieve the above objectives, the present invention provides a display panel, including a substrate layer 1, a thin film transistor layer 2, a flat layer 3, a pixel definition layer 4 and a thin film packaging layer 5 arranged in turn.

The substrate layer 1 is a PI film, i.e. a polyimide film, which serves as a base of the display panel. The polyimide film is an insulating material with good properties in the world and has strong tensile strength. It is made of pyromellitic dianhydride and diaminodiphenyl ether by condensation in strong polar solvent, film casting and imidization.

The thin film transistor layer 2 includes a buffer layer 21, a first grid insulating layer 22, a second grid insulating layer 23 and a barrier layer 24. The buffer layer 21 is disposed on the substrate layer 1, the first grid insulating layer 22 is disposed on the buffer layer 21, the second grid insulating layer 23 is disposed on the first grid insulating layer 22, and the barrier layer 24 is disposed on the second grid insulating layer 23. In the embodiment, the material of the first grid insulating layer 22 and the second grid insulating layer 23 is silicon nitride. Silicon oxide and silicon nitride can also be used, depending on the need, there is no limit. The flat layer 3 and the pixel definition layer 4 are made of a transparent organic material, which has good elasticity and flexibility, and plays the role of flattening and cushioning the stress of the film layer.

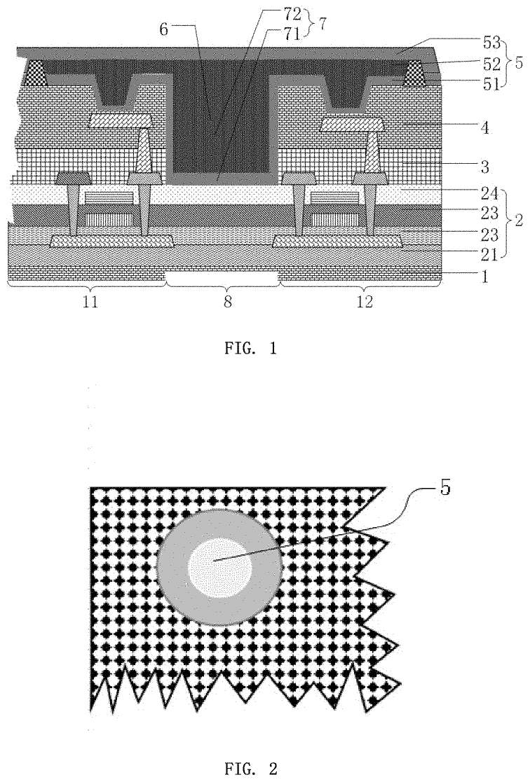

Please referring to FIG. 2, FIG. 2 is a top view of the display panel provided by the embodiment of the present invention. The pixel definition layer 4 forms a first pixel 11 and a second pixel 12, which are adjacent but spaced. The pixel definition layer 4 and the flat layer 3 are provided with a through hole 6 between the first pixel and the second pixel. A width of the through hole 6 is less than a distance between the first pixel 11 and the second pixel 12.

The through hole 6 passes down through the pixel definition layer 4 to the flat layer 3. That is to say, in the through hole 6, the flat layer 3 and the pixel definition layer 4 are removed, and the removed part is filled with a filling layer 7.

The thin film packaging layer 5 includes a first inorganic layer 51, an organic layer 52 arranged on the first inorganic layer 51 and a second inorganic layer 53 arranged on the organic layer 52.

The filling layer 7 includes a first filling layer 71 on an inner wall of the through hole 6 and a second filling layer 72 on the first filling layer 71. The first filling layer 71 and the first inorganic layer 51 are in the same layer, and the second filling layer 72 and the organic layer 52 are in the same layer. This structure improves the transmittance to a certain extent, further reduces the diameter of the hole, and achieves the effect of great screen proportion.

Wherein the filling layer 7 is formed by inkjet printing, the through hole 6 is formed by laser radium drilling. A cross-section shape of the through hole 6 is rectangular. The substrate layer 1 is provided with a groove 8 corresponding to the through hole 6 on one side of the substrate layer 1 away from the thin film transistor layer 2 for accommodating an electronic component. The groove 8 is formed by laser cutting. Its depth is 20%-80% of a thickness of the substrate layer 1. In the embodiment, the depth of the groove 8 is 30% of the thickness of the substrate layer 1.

In other embodiments, the depth of the groove can be determined according to the need, and there is no limit, as long as the depth of the groove can be guaranteed to be less than the thickness of the substrate layer.

### Embodiment 2

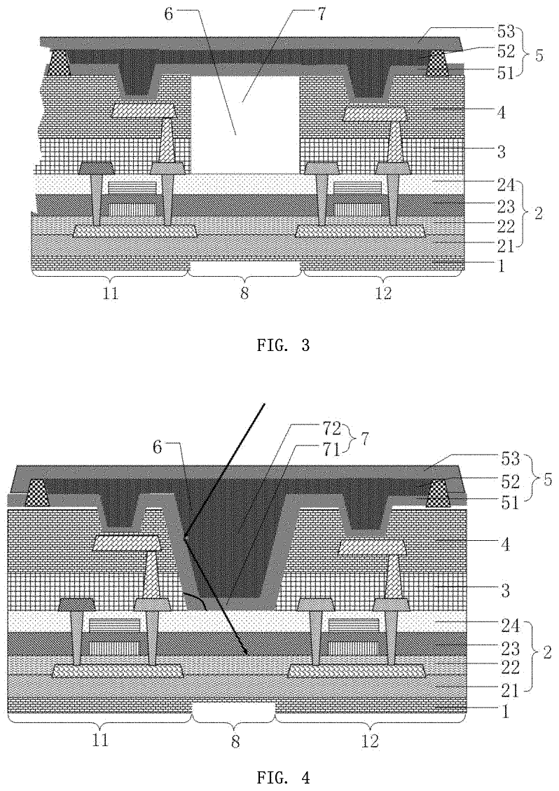

Please refer to FIG. 3, FIG. 3 is a sectional schematic view of the display panel provided by the embodiment. The structure of the display panel in Embodiment 2 is roughly the same as that in Embodiment 1. The same structure can be referred to in the above description, which will not be repeated here. The difference between the both is that: the material of the filling layer 7 in Embodiment 2 is a transparent organic material, and its transmittance is greater than that of the pixel definition layer 4 and the flat layer 3. Therefore, this design improves the transmittance to a certain extent, further reduces the diameter of the hole, and achieves the effect of great screen proportion.

### Embodiment 3

Please refer to FIG. 4, FIG. 4 is a sectional schematic view of the display panel provided by the embodiment. The structure of the display panel in Embodiment 3 is roughly the same as that in Embodiment 1. The same structure can be referred to in the above description, which will not be repeated here. The difference between the both is that: the cross-section shape of the through hole 6 is inverted trapezoid. An angle between the sidewall and the bottom of the through hole 6 is obtuse. With the increase of the angle, the thickness of the thin film evaporated on the sidewall increases. But when the angle of the sidewall and the bottom of the through hole 6 is greater than 120 degrees, the sidewall of the through hole 6 will not reflect. Therefore, the angle between the sidewall and the bottom of the through hole 6 needs to be controlled between 90 degrees and 120 degrees, the sidewall of the through hole 6 can act as a reflector to reflect light, whereby the electronic component placed in the groove 8 can gather more lights. In the embodiment, the angle between the sidewall and the bottom of the through hole 6 can be optimized to 120 degrees.

In other embodiments, the angle between the sidewall and the bottom of the through hole 6 can be determined according to the need, there is no limit, as long as it can ensure that the sidewall of the through hole 6 can act as a reflector for reflecting the lights entering the display panel from outside.

### Embodiment 4

The embodiment provides a display device, including a body. The display panel according to the present invention is disposed on the body. And the electronic component is disposed on the body and located under the through hole of the display panel.

The beneficial effects of the present invention lie in: the present invention provides the display panel and the display device. There forms the through hole between the two pixels, and removes the flat layer and the pixel definition layer in the through hole. The removed part can be replaced by a material with greater transmittance, and the thickness of the substrate layer corresponding to the through hole is reduced appropriately to improve the transmittance of the electronic components under the substrate layer. The diameter of the through hole is reduced for obtaining the full screen or the greater screen proportion. Moreover, an original line layer and the thin film packaging layer are retained to provide a maximum barrier function for the water and oxygen in the through hole area.

The above description is only the preferred embodiments of the present invention. It should be pointed out that the person skilled in the art may make various changes and embellishments without departing from the principle of the present invention, so the changes and embellishments shall also be regarded as the scope of protection of the present invention.

What is claimed is:

1. A display panel, including a substrate layer, a thin film transistor layer, a flat layer, a pixel definition layer and a thin film packaging layer arranged in turn; the pixel definition layer forming a first pixel and a second pixel, which are adjacent but spaced; wherein the pixel definition layer and the flat layer are provided with a through hole between the first pixel and the second pixel; the through hole being filled with a filling layer.

2. The display panel as claimed in claim 1, wherein the filling layer adopts a transparent organic material, a transmittance of which is greater than that of the pixel definition layer and the flat layer.

3. The display panel as claimed in claim 1, wherein the thin film packaging layer includes a first inorganic layer, an organic layer arranged on the first inorganic layer, and a second inorganic layer arranged on the organic layer.

4. The display panel as claimed in claim 3, wherein the filling layer includes a first filling layer on an inner wall of the through hole and a second filling layer on the first filling layer; the first filling layer and the first inorganic layer are in the same layer, and the second filling layer and the organic layer are in the same layer.

5. The display panel as claimed in claim 1, wherein the substrate layer is provided with a groove corresponding to the through hole on one side of the substrate layer away from the thin film transistor layer for accommodating an electronic component.

6. The display panel as claimed in claim 5, wherein a depth of the groove is 20%-80% of a thickness of the substrate layer.

7. The display panel as claimed in claim 1, wherein a cross-section shape of the through hole is rectangular.

8. The display panel as claimed in claim 1, wherein a cross-section shape of the through hole is inverted trapezoid.

9. The display panel as claimed in claim 8, wherein the through hole forms an angle between a sidewall and a bottom thereof, and the angle is between 90 degrees and 120 degrees.

10. A display device, including a housing, characterized in that, the housing disposing the display panel as claimed in claim 1, and further disposing an electronic component, which is located under the through hole of the display panel.

11. The display device as claimed in claim 10, wherein the filling layer adopts a transparent organic material, a transmittance of which is greater than that of the pixel definition layer and the flat layer.

12. The display device as claimed in claim 10, wherein the thin film packaging layer includes a first inorganic layer, an organic layer arranged on the first inorganic layer, and a second inorganic layer arranged on the organic layer.

13. The display device as claimed in claim 12, wherein the filling layer includes a first filling layer on an inner wall of the through hole and a second filling layer on the first filling layer; the first filling layer and the first inorganic layer are in the same layer, and the second filling layer and the organic layer are in the same layer.

14. The display device as claimed in claim 10, wherein the substrate layer is provided with a groove corresponding to the through hole on one side of the substrate layer away from the thin film transistor layer for accommodating an electronic component.

15. The display device as claimed in claim 14, wherein a depth of the groove is 20%-80% of a thickness of the substrate layer.

16. The display device as claimed in claim 10, wherein a cross-section shape of the through hole is rectangular.

17. The display device as claimed in claim 10, wherein a cross-section shape of the through hole is inverted trapezoid.

18. The display device as claimed in claim 17, wherein the through hole forms an angle between a sidewall and a bottom thereof, and the angle is between 90 degrees and 120 degrees.
